(19) United States
(12) Patent Application Publication
(10) Pub. No.: US 2025/0277098 A1
(43) Pub. Date: Sep. 4, 2025

(54) COMPOSITION FILM AND HEAT RADIATING MEMBER

(71) Applicant: FUJIFILM Business Innovation Corp., Tokyo (JP)

(72) Inventors: Taiki NAGAMATSU, Kanagawa (JP); Kenji KAJIWARA, Kanagawa (JP); Hiroaki TANAKA, Kanagawa (JP); Ryohei YOSHIKAWA, Kanagawa (JP); Tomotake INAGAKI, Kanagawa (JP); Masayuki SEKO, Kanagawa (JP)

(73) Assignee: FUJIFILM Business Innovation Corp., Tokyo (JP)

(21) Appl. No.: 18/788,154

(22) Filed: Jul. 30, 2024

(30) Foreign Application Priority Data
Feb. 29, 2024 (JP) 2024-030668

(51) Int. Cl. C08K 3/28; C08J 5/18; C08K 3/14

(52) U.S. Cl. CPC C08K 3/28; C08J 5/18; C08K 3/14; C08K 2003/282; C08K 2201/001; C08K 2201/004

(57) ABSTRACT

A composition film containing at least one compound selected from the group consisting of a resin and a rubber and a filler which is dispersed in the compound and has an average maximum length of 0.05 μm or more and 10 μm or less, in which a density is 1.50 g/cm³ or more and 2.80 g/cm³ or less, and in a spatial distribution of the filler presented in an evaluation region, an integrated value of a statistical quantity L(r) represented by Equation (1) at an interparticle distance r of 0.05 μm or more and 0.30 μm or less is 0 or more and 0.30 or less.

$$L ( r ) := \sqrt{K ( r ) / π} - r \qquad ( 1 )$$

(In Equation (1), r represents the interparticle distance, and K(r) represents a Ripley's K function K(r) represented by Equation (2).)

$$K ( r ) := \frac{{\sum }_{i \neq j}^{N} 1 ( \vert {X}_{i} - {X}_{j} \vert \leq r ) / s ( \vert {X}_{i} - {X}_{j} \vert )}{{λ}^{2}} \qquad ( 2 )$$

(In Equation (2), 1(|Xᵢ−Xⱼ|≤r) represents an indicator function, Xᵢ and Xⱼ each represent a coordinate of point i or point j, |Xᵢ−Xⱼ| represents a Euclidean distance between the coordinate Xᵢ and the coordinate Xⱼ, r represents the interparticle distance, s(|Xᵢ−Xⱼ|) represents an edge correction factor s(x) of the evaluation region represented by Equation (3), x=|Xᵢ−Xⱼ| is satisfied, N represents a total number of particles in the evaluation region, and λ represents a number density of particles in the evaluation region.)

$$s ( x ) := {L}_{x} {L}_{y} - \frac{x}{π} ( 2 {L}_{x} + 2 {L}_{y} - x ) \qquad ( 3 )$$

(In Equation (3), Lₓ and L_{y} each represent a length (μm) of sides of the evaluation region in an x-axis direction and a y-axis direction, x=|Xᵢ−Xⱼ| is satisfied, Xᵢ and Xⱼ each represent a coordinate of point i or point j, and |Xᵢ−Xⱼ| represents a Euclidean distance between the coordinate Xᵢ and coordinate Xⱼ.)

### CROSS-REFERENCE TO RELATED APPLICATIONS

This application is based on and claims priority under 35 USC 119 from Japanese Patent Application No. 2024-030668 filed Feb. 29, 2024.

### BACKGROUND

### (i) Technical Field

The present disclosure relates to a composition film and a heat radiating member.

### (ii) Related Art

JP7307377B discloses a filler-containing film including a filler distributed layer in which fillers are regularly disposed in a resin layer, in which an area occupancy rate of the filler in a plan view is 25% or less, a ratio La/D between a layer thickness La of the resin layer and an average diameter D of the fillers is 0.3 or more and 1.3 or less, and a number proportion of the fillers present in a non-contact state with each other is 95% or more with respect to the entire fillers.

In addition, JP4764220B discloses a thermally conductive sheet which consists of a binding agent and a thermally conductive filler and/or a soft magnetic powder, and has a thermal conductivity and an electromagnetic interference suppression effect, in which a contact thermal resistance with a smooth surface and a corrugated surface is small.

In addition, JP2021-086920A discloses an electronic apparatus including a thermal conductive sheet between a heat generating component and a heat radiating component, in which the thermal conductive sheet contains a rubber and a filler dispersed in the rubber, and in a binarized image of a cross section of the rubber in a thickness direction, an average area proportion of large-particle diameter fillers having an equivalent circle diameter of 5 μm or more among the fillers is in a range of 20% or more and 50% or less, an average arrangement degree fL of the large-particle diameter fillers is in a range of 0.00 or more and 0.15 or less, an average area proportion of small-particle diameter fillers having an equivalent circle diameter of less than 5 μm among the fillers is in a range of 10% or more and 30% or less, an average arrangement degree fS of the small-particle diameter fillers is in a range of 0.20 or more and 0.50 or less, and an average arrangement angle ΦS of the small-particle diameter fillers is in a range of 60° or more and 120° or less.

### SUMMARY

Aspects of non-limiting embodiments of the present disclosure related to a composition film in which a decrease in heat dissipation after repetition of heat radiation is suppressed as compared with a composition film in which an average maximum length of fillers is more than 10 μm, a composition film in which a density is less than 1.50 g/cm³, and a composition film in which an integrated value of a statistical quantity L(r) represented by Equation (1) is more than 0.30, and a heat radiating member including the composition film.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

Means for addressing the above object include the following aspect.

According to an aspect of the present disclosure, there is provided a composition film containing at least one compound selected from the group consisting of a resin and a rubber and a filler which is dispersed in the compound and has an average maximum length of 0.05 μm or more and 10 μm or less, in which a density is 1.50 g/cm³ or more and 2.80 g/cm³ or less, and in a spatial distribution of the filler presented in an evaluation region, an integrated value of a statistical quantity L(r) represented by Equation (1) at an interparticle distance r of 0.05 μm or more and 0.30 μm or less is 0 or more and 0.30 or less.

$$L ( r ) := \sqrt{K ( r ) / π} - r \qquad ( 1 )$$

(In Equation (1), r represents the interparticle distance, and K(r) represents a Ripley's K function K(r) represented by Equation (2).)

$$K ( r ) := \frac{{\sum }_{i \neq j}^{N} 1 ( \vert {X}_{i} - {X}_{j} \vert \leq r ) / s ( \vert {X}_{i} - {X}_{j} \vert )}{{λ}^{2}} \qquad ( 2 )$$

(In Equation (2), 1(|Xᵢ−Xⱼ|≤r) represents an indicator function, Xᵢ and Xⱼ each represent a coordinate of point i or point j, |Xᵢ−Xⱼ| represents a Euclidean distance between the coordinate Xᵢ and the coordinate Xⱼ, r represents the interparticle distance, s(|Xᵢ−Xⱼ|) represents an edge correction factor s(x) of the evaluation region represented by Equation (3), x=|Xᵢ−Xⱼ| is satisfied, N represents a total number of particles in the evaluation region, and λ represents a number density of particles in the evaluation region.)

$$s ( x ) := {L}_{x} {L}_{y} - \frac{x}{π} ( 2 {L}_{x} + 2 {L}_{y} - x ) \qquad ( 3 )$$

(In Equation (3), Lₓ and L_{y} each represent a length (μm) of sides of the evaluation region in an x-axis direction and a y-axis direction, x=|Xᵢ−Xⱼ| is satisfied, Xᵢ and Xⱼ each represent a coordinate of point i or point j, and |Xᵢ−Xⱼ| represents a Euclidean distance between the coordinate Xᵢ and coordinate Xⱼ.)

### DETAILED DESCRIPTION

Hereinafter, exemplary embodiments that are examples of the present disclosure will be described. The description and examples of these exemplary embodiments illustrate the exemplary embodiments and do not limit the scopes of the exemplary embodiments.

In the present disclosure, a numerical range described using “to” represents a range including numerical values listed before and after “to” as the minimum value and the maximum value respectively.

Regarding the numerical ranges described in stages in the present disclosure, the upper limit value or lower limit value of one numerical range may be replaced with the upper limit value or lower limit value of another numerical range described in stages. In addition, in the present disclosure, the upper limit or lower limit of a numerical range may be replaced with values described in examples.

In the present disclosure, in a case where an exemplary embodiment is described with reference to drawings, the configuration of the exemplary embodiment is not limited to the configuration shown in the drawings. In addition, the sizes of members in each drawing are conceptual, and a relative relationship between the sizes of the members is not limited thereto.

In the present disclosure, each component may include a plurality of corresponding substances. In a case where the amount of each component in a composition is mentioned in the present disclosure, and there are a plurality of kinds of substances corresponding to each component in the composition, unless otherwise specified, the amount of each component means the total amount of the plurality of kinds of substances present in the composition.

### Composition Film

The composition film according to the exemplary embodiment of the present disclosure contains at least one compound selected from the group consisting of a resin and a rubber, and a filler dispersed in the compound.

The filler has an average maximum length of 0.05 μm or more and 10 μm or less.

The density of the composition film is 1.50 g/cm³ or more and 2.80 g/cm³ or less.

Furthermore, in the spatial distribution of the filler present in an evaluation region in the composition film, an integrated value of a statistical quantity L(r) represented by Equation (1) described later at an interparticle distance r of 0.05 μm or more and 0.30 μm or less is 0 or more and 0.30 or less. In the present disclosure, the evaluation region is set to a range of 6.3 μm×4.2 μm.

The composition film according to the exemplary embodiment of the present disclosure has the above-described configuration, thereby a decrease in heat dissipation after repetition of the heat radiation is suppressed. The reason why the effect is exhibited is assumed as follows.

As the composition film used as the heat radiating member, a composition film having a high thermal conductivity is used by adding a large amount of a filler which contributes to thermal conduction with respect to a binder such as a resin and rubber. Such a composition film is used, for example, in a member for reducing thermal resistance in a housing having a heat source inside. However, in the composition film in which the large amount of the filler has been added, the heat dissipation may be decreased as the heat dissipation is repeated, because of the plastic deformation due to heat.

On the other hand, in the composition film according to the exemplary embodiment of the present disclosure, the high density of the composition film of 1.50 g/cm³ or more means that the composition film contains a large amount of the filler. The heat trapped in the heat dissipation object (for example, an electronic component or the like) is easily released through the composition film in contact with the heat dissipation object by the two reasons, which are, since the density of the composition film is high, that the thermal conductivity is increased and the thermal resistance is reduced, and that the specific heat of the composition film is small.

In addition, in a case where the small filler having an average maximum length of 10 μm or less is used, the number density of the filler is increased. In a case where the number density of the filler is high, a thermal conduction path by the filler is likely to be formed inside the composition film.

Furthermore, the integrated value of the statistical quantity L(r) represented by Equation (1) described later is 0.30 or less, and the dispersion state of the filler inside the composition film is well maintained. Therefore, although the composition film contains a large amount of the filler, the dispersion state of the filler inside the composition film is well maintained, thereby the plastic deformation due to heat is reduced. Even after the repetition of the heat dissipation, the plastic deformation due to heat is suppressed, thereby the contact thermal resistance of the composition film is maintained to be small. That is, the decrease in heat dissipation is suppressed, and the composition film can be used for a long period of time while maintaining high performance.

As described above, according to the composition film according to the exemplary embodiment of the present disclosure, a decrease in heat dissipation after repetition of the heat radiation is suppressed.

Hereinafter, the composition film according to the exemplary embodiment of the present disclosure will be described in more detail.

### Density

The density of the composition film is 1.50 g/cm³ or more and 2.80 g/cm³ or less. The high density of 1.50 g/cm³ or more means that a large amount of the filler is contained, thereby the heat dissipation from a heat dissipation object (for example, an electronic component) in contact with the composition film are enhanced. On the other hand, the density of 2.80 g/cm³ or less means that the content of the compound is not too low, and the followability of the composition film with respect to the heat dissipation object, that is, the performance of increasing the contact area can be enhanced.

Furthermore, the density of the composition film is, for example, preferably 1.60 g/cm³ or more and 2.80 g/cm³ or less, and more preferably 1.70 g/cm³ or more and 2.60 g/cm³ or less.

The density of the composition film is a value obtained by the measurement according to the water displacement method of JIS-K7112:1999 “Plastics—methods for measuring density and specific gravity of non-cellular plastics”. As a dipping solution, new distilled water containing 0.1% or less of a wetting agent is used to remove air bubbles.

### Integrated Value of Statistical Quantity L(r)

In the composition film, in the spatial distribution of the filler present in the evaluation region (in the present disclosure, the evaluation region is set to a range of 6.3 μm×4.2 μm), an integrated value of a statistical quantity L(r) represented by Equation (1) in an interparticle distance r of 0.05 μm or more and 0.30 μm or less is 0 or more and 0.30 or less. In a case where the integrated value of the statistical quantity L(r) is 0.30 or less, the dispersion state of the filler inside the composition film is well maintained, and the decrease in heat dissipation is suppressed even after repeating the heat radiation.

The integrated value of the statistical quantity L (r) in the composition film is, for example, preferably 0 or more and 0.28 or less, and more preferably 0 or more and 0.26 or less.

Here, a method of obtaining the integrated value of the statistical quantity L(r) represented by Equation (1) will be described. First, the spatial distribution of the filler in the composition film is obtained by observing a cross section of the composition film with a scanning electron microscope (manufactured by Hitachi High-Tech Corporation, model number: SU8010) at a magnification of 20,000 times, and binarizing the obtained 256-level grayscale image at a threshold value of 128 by using an analysis software (free software “ImageJ”). Then, a statistical quantity L(r) at an interparticle distance r of 0.05 μm or more and 0.30 μm or less is calculated at intervals of 0.05 μm based on the above equation, and an integrated value in a range of 0.05 μm or more and 0.30 μm or less is determined and adopted as “L(r) integrated value”.

The number density λ of the particles (filler) in Equation (2) is obtained from the observed two-dimensional image.

In addition, the average maximum length of the filler, which will be described later, is obtained by obtaining the length of the longest portion for each filler from the observed two-dimensional image and calculating the arithmetic average of the lengths.

$$L ( r ) := \sqrt{K ( r ) / π} - r \qquad ( 1 )$$

(In Equation (1), r represents the interparticle distance, and K(r) represents a Ripley's K function K(r) represented by Equation (2).)

$$K ( r ) := \frac{{\sum }_{i \neq j}^{N} 1 ( \vert {X}_{i} - {X}_{j} \vert \leq r ) / s ( \vert {X}_{i} - {X}_{j} \vert )}{{λ}^{2}} \qquad ( 2 )$$

(In Equation (2), 1(|Xᵢ−Xⱼ|≤r) represents an indicator function, Xᵢ and Xⱼ each represent a coordinate of point i or point j, |Xᵢ−Xⱼ| represents a Euclidean distance between the coordinate Xᵢ and the coordinate Xⱼ, r represents the interparticle distance, s(|Xᵢ−Xⱼ|) represents an edge correction factor s(x) of the evaluation region represented by Equation (3), x=|Xᵢ−Xⱼ| is satisfied, N represents a total number of particles in the evaluation region, and λ represents a number density of particles in the evaluation region.)

$$s ( x ) := {L}_{x} {L}_{y} - \frac{x}{π} ( 2 {L}_{x} + 2 {L}_{y} - x ) \qquad ( 3 )$$

(In Equation (3), Lₓ and L_{y} each represent a length (μm) of sides of the evaluation region in an x-axis direction and a y-axis direction, x=|Xᵢ−Xⱼ| is satisfied, Xᵢ and Xⱼ each represent a coordinate of point i or point j, and |Xᵢ−Xⱼ| represents a Euclidean distance between the coordinate Xᵢ and coordinate Xⱼ.)

To enhance the dispersibility of the filler inside the composition film and to set the integrated value of the holding statistical quantity L(r) to the above-described range, for example, it is preferable to control the particle diameter of the filler and to control the cohesive force of the filler in the composition film in a case of obtaining the composition film.

### Filler

### Average Maximum Length of Filler

The filler contained in the composition film has an average maximum length of 0.05 μm or more and 10 μm or less. In a case where the average maximum length is 10 μm or less, the number density of the fillers is increased, a thermal conduction path by the filler is easily formed inside the composition film, and the heat dissipation from a heat dissipation object (for example, an electronic component or the like) in contact with the composition film are enhanced. On the other hand, in a case where the average maximum length is 0.05 μm or more, a thermal conduction path by the filler is also easily formed inside the composition film, and the heat dissipation from a heat dissipation object (for example, an electronic component or the like) in contact with the composition film are enhanced.

The average maximum length of the filler is, for example, preferably 1.0 μm or more and 10 μm or less and more preferably 2.0 μm or more and 6.5 μm or less.

### Shape of Filler

Examples of a shape of the filler contained in the composition film include a spherical filler, a needle-like filler, a flat plate-like filler, and the like.

### Material of Filler

Examples of a material of the filler include a carbon material, a ceramic material, a metal oxide material, and the like. Examples of the filler of the carbon material include carbon fibers such as carbon nanofibers and carbon nanotubes, graphite particles, flake graphite, and the like. Examples of the filler of the ceramics material include ceramic fibers, ceramic particles, and flat plate-like ceramics, which is formed of aluminum nitride, boron nitride, silicon carbide, and the like. Examples of the filler of the metal oxide material include acicular metal oxide, metal oxide particles, flat plate-like metal oxide, and the like, which is formed of alumina, boehmite (alumina monohydrate), silica, titania, zirconia, magnesium oxide, tin oxide, zinc oxide, barium oxide, and the like.

Among these, from the viewpoint of enhancing the heat dissipation, for example, at least one selected from the group consisting of silicon carbide, aluminum nitride, and boron nitride is preferably contained as the filler, and at least one selected from the group consisting of aluminum nitride and boron nitride is more preferably contained as the filler.

### Compound

### Type of Compound

The composition film contains at least one compound selected from the group consisting of a resin and a rubber. Examples of the compound include resins such as an acrylic resin, a polyester (particularly, an aromatic polyester), an epoxy resin, a polyimide resin, a polyamide resin, a polyamidoimide resin, a thermotropic liquid crystal polymer, a fluororesin, and a silicone resin, and rubbers such as a fluororubber, a silicone rubber, and a fluorosilicone rubber. One type of compound may be used alone, or two or more types of compounds may be mixed and used. From the viewpoint of heat resistance of the composition film, for example, a polyimide resin is preferable.

From the viewpoint of the flexibility and the durability of the composition film, the content (% by volume) of the compound contained in the composition film is, for example, preferably 20% by volume or more and 60% by volume or less and more preferably 30% by volume or more and 40% by volume or less.

### Physical Properties of Composition Film

From the viewpoint of enhancing the heat dissipation, the insulation breakdown voltage of the composition film is, for example, preferably 5.0 kV/mm or more and more preferably 6.0 kV/mm or more.

On the other hand, from the viewpoint of a trade-off relationship with the thermal resistance, the upper limit value of the insulation breakdown voltage is, for example, preferably 20.0 kV/mm or less, more preferably 18.0 kV/mm or less, and still more preferably 11.5 kV/mm or less.

The insulation breakdown voltage of the composition film is measured according to JIS C2110-2:2016 (Part 2: Test by applying direct-current voltage).

The Shore hardness of the composition film is, for example, preferably 25 Hs or more and 80 Hs or less and more preferably 25 Hs or more and 75 Hs or less. The Shore hardness of 80 Hs or less enhances the followability to the heat dissipation object. The Shore hardness of 25 Hs or more can enhance the strength of the composition film.

The Shore hardness of the composition film is measured with a microgum hardness tester (Type-C). Conditions in a case of the measurement are in accordance with JIS Z2246:2000.

From the viewpoint of enhancing the heat dissipation, the thermal conductivity of the composition film is, for example, preferably 5.0 W/mK or more and more preferably 6.0 W/mK or more.

On the other hand, from the viewpoint of flexibility of the sheet for reducing the thermal resistance, the upper limit value of the thermal conductivity is, for example, preferably 30.0 W/mK or less, more preferably 20.0 W/mK or less, and still more preferably 18.0 W/mK or less.

In the measurement of the thermal conductivity of the composition film, the composition film is cut into a square having a side of 2 mm in the axial direction and a side of 2 mm in the circumferential direction, and this is used as a measurement sample. The thermal diffusivity of the sample is measured at a room temperature (25° C. 3° C.) using a thermal diffusivity measuring device ai-phase (ai˜Phase Co., Ltd.), and the thermal conductivity (W/m·K) of the sample is calculated by multiplying the thermal diffusivity by specific heat and density.

From the viewpoint of enhancing the heat dissipation, the thermal resistance of the composition film is, for example, preferably 1.0×10⁻³ m²K/W or less and more preferably 5.0×10⁻⁴ m²K/W or less.

The thermal resistance of the composition film is calculated from a temperature difference between the upper and lower parts and a heat flow by interposing the composition film between a cooling plate and a heater and applying a load thereto. The lower limit of the thermal resistance is 1.0×10⁻⁸ cm²K/W.

The composition film according to the exemplary embodiment of the present disclosure may be a flat film or a tubular film. Examples of the use of the composition film according to the exemplary embodiment of the present disclosure include a sheet or the like which is installed in a heat dissipation object such as an electronic apparatus for the purpose of heat absorption and heat release.

### Heat Radiating Member

The heat radiating member according to the exemplary embodiment of the present disclosure has the above-described composition film. The heat radiating member is installed on a heat dissipation object such as an electronic apparatus for the purpose of heat absorption and heat release.

The heat radiating member may have the composition film as a single layer film, or may have a laminated film in which two or more of the composition films are laminated.

The composition film may be an aspect in which in a case of having a laminated film, a compound of each layer is a resin or rubber of a different type, and each layer is given a separate role (for example, laminating layers having different hardnesses).

### Method for Manufacturing Composition Film

Examples of a method for manufacturing the composition film according to the exemplary embodiment of the present disclosure include a manufacturing method in which Steps (1) to (3) are sequentially performed.
Step (1): The compound and the filler are mixed to prepare a coating liquid. A solvent or a dispersion medium is also mixed as needed.
Step (2): Abase body is coated with the coating liquid and the coating liquid is dried to form a coating film.
Step (3): The coating film is calcined to obtain a composition film.

By using a cylindrical mold as the base body in Step (2), a tubular composition film can be manufactured.

### EXAMPLES

Hereinafter, exemplary embodiments of the invention will be described in detail based on examples, but the exemplary embodiments of the invention are not limited to the examples.

In the following description, the synthesis, the treatment, the production, and the like are carried out at room temperature (25° C.±3° C.) unless otherwise specified.

### Manufacture of Composition Film

### Examples A1 to A8 and Comparative Examples A1 to A4 (Rubber)

The filler shown in Table 1 is added to the rubber (Si rubber) shown in Table 1 such that the content shown in Table 1 is reached, and mixed, and the mixture is kneaded with a three-roll mill to prepare a coating liquid (A).

An outer circumferential surface of a cylindrical mold (diameter of 30 mm, width of 420 mm) made of aluminum is coated with the coating liquid (A), and the coating liquid (A) is dried for 80 minutes at a temperature of 100° C. After that, the cylindrical mold including the coating film is displaced in a heating furnace and is heated and calcined for 40 minutes at a temperature of 380° C. A coating amount of the coating liquid (A) is adjusted such that the average film thickness of the composition film is 100 μm. A calcined film is pulled out from the cylindrical mold to obtain a composition film.

Details of the rubber and the filler shown in Table 1 are as follows.

### Rubber

Si rubber (silicone rubber, manufactured by Shin-Etsu Chemical Co., Ltd., product name: X-34-2826-A/B)

### Filler

### Example A1

Aluminum nitride (average maximum length: 7 μm, manufactured by TOYO ALUMINIUM K.K., product name: TFZ-A10P)

### Example A2

Aluminum nitride (average maximum length: 3 μm, manufactured by TOYO ALUMINIUM K.K., product name: TFZ-A05P)

### Comparative Example A1

Aluminum nitride (average maximum length: 15 μm, manufactured by TOYO ALUMINIUM K.K., product name: TFZ-A15P)

### Comparative Example A2

Aluminum nitride (average maximum length: 0.1 μm, manufactured by TOYO ALUMINIUM K.K., product name: TFZ-N01P)

### Examples A3 and A7

Silicon carbide (average maximum length: 2 μm, manufactured by Kojundo Chemical Lab. Co., Ltd., product name: SII01PB)

### Example A4

Boron nitride (average maximum length: 8 μm, manufactured by 3M Japan Limited, product name: Platelets CFP 012)

### Examples A5, A6, A8, and Comparative Example A3

Graphite (average maximum length: 6 μm, manufactured by Nippon Graphite Industries, Co., Ltd., product name: JB-5)

### Comparative Example A4

Graphite (average maximum length: 0.1 μm, manufactured by Nippon Techno-Carbon Co., Ltd., product name: GF-130)

### Examples B1 to B20 and Comparative Examples B1 to B12 (Resin)

The filler shown in Tables 2 to 4 is added to the resin (acrylic resin, polyimide, aromatic polyester, or epoxy resin) shown in Tables 2 to 4 such that the content of the filler shown in Tables 2 to 4 is reached, and mixed, and the mixture is kneaded with a three-roll mill to prepare a coating liquid (B).

The coating liquid (B) is applied onto an outer peripheral surface of a cylindrical mold (diameter of 30 mm, width of 420 mm) made of aluminum and having a film in which a cured resin is peelable on a surface, and dried at a temperature of 115° C. for 15 minutes. After that, the cylindrical mold including the coating film is displaced in a heating furnace and is heated and calcined for 2 hours at a temperature of 200° C. A coating amount of the coating liquid (B) is adjusted such that the average film thickness of the composition film is 100 μm. A calcined film is pulled out from the cylindrical mold to obtain a composition film.

Details of the resin and the filler shown in Tables 2 to 4 are as follows.

### Resin

Acrylic resin (manufactured by DIC Corporation, product name: ACRYDIC 36-068)
Polyimide (polyamic acid solution, solid content of 18%, U-Imide Varnish KX-R, manufactured by Unitika Ltd.)
Aromatic polyester (manufactured by SUMITOMO CHEMICAL COMPANY, LIMITED, product name: SUMIKASUPER)
Epoxy resin (manufactured by Dai Nippon Toryo Company, Limited, product name: EPONICS PH)

### Filler

### Examples B1, B6, B11, and B16

Aluminum nitride (average maximum length: 7 μm, manufactured by TOYO ALUMINIUM K.K., product name: TFZ-A10P)

### Examples B2, B12, and B17

Aluminum nitride (average maximum length: 1 μm, manufactured by Tokuyama Corporation, product name: HF-01)

### Comparative Examples B1, B4, B7, and B10

Aluminum nitride (average maximum length: 0.8 μm, manufactured by Tokuyama Corporation, product name: HF-01D)

### Examples B3 and B18

Boron nitride (average maximum length: 4 μm, manufactured by 3M Japan Limited, product name: Platelets CFP 003SF)

### Example B7, B13

Boron nitride (average maximum length: 8 μm, manufactured by 3M Japan Limited, product name: Platelets CFP 012)

### Examples B4, B9, B14, B19, and Comparative Examples B8 and B11

Graphite (average maximum length: 6 μm, manufactured by Nippon Graphite Industries, Co., Ltd., product name: JB-5)

### Comparative Examples B3, B6, B9, and B12

Graphite (average maximum length: 0.1 μm, manufactured by Nippon Techno-Carbon Co., Ltd., product name: GF-130)

### Examples B5, B10, B15, and B20

Silicon carbide (average maximum length: 2 μm, manufactured by Kojundo Chemical Lab. Co., Ltd., product name: SII01PB)

### Example B8 and Comparative Example B2

Carbon nanofiber (CNF, average maximum length: 1 μm, manufactured by Resonac Holdings Corporation, product name: VGCF-H)

### Comparative Example B5

Carbon nanofiber (CNF, average maximum length: 6 μm, manufactured by Resonac Holdings Corporation, product name: VGCF-H)

For the composition film obtained in each of Examples and Comparative Examples, the density, the integrated value of the statistical quantity L (r), the insulation breakdown voltage, the Shore hardness, the thermal conductivity, and the thermal resistance are measured by the above-described methods. The results are shown in Tables 1 to 4.

### Heat Dissipation in Long-Term Test

For each of the composition films obtained in Examples and Comparative Examples, the thermal resistance after a heat cycle test of 200 hours at 125° C./−55° C. is measured with respect to the value of thermal resistance (T=0). The evaluation is performed according to the following standard.
AA: a value of 90% or more and 100% or less
A: a value of 80% or more and less than 90%
B: a value of 60% or more and less than 80%
C: a value of less than 60%

### Thermal Resistance

The thermal resistance value is calculated from a temperature difference between the upper and lower parts and a heat flow by interposing the composition film obtained in each of Examples and Comparative Examples between a cooling plate and a heater and applying a load thereto. The lower limit of the thermal resistance value is 1.0×10⁻⁸ cm²K/W. The evaluation is performed according to the following standard.
AA: 5.0×10⁻⁴ m²K/W or less
A: more than 5.0×10⁻⁴ m²K/W and 1.0×10⁻³ m²K/W or less
B: more than 1.0×10⁻³ m²K/W and 5.0×10⁻² m²K/W or less.
C: more than 5.0×10⁻² m²K/W

### Appropriateness of Heat Radiating Member

The evaluation is performed according to the following standard.
AA: excellent in heat dissipation in the long-term test and satisfies with all of insulation and flexibility
A: excellent in heat dissipation in a long-term test and satisfies with insulation or flexibility
B: slightly poor in heat dissipation in the long-term test
C: poor in heat dissipation in the long-term test

TABLE 1

| | | Filler | | | | Integrated | | | | | | Appropri- |
|---|---|---|---|---|---|---|---|---|---|---|---|---|
| | | | Average | | | value of | Thermal | | Heat | Insulation | | ateness |
| | | | maximum | Content | | statistical | conduc- | Thermal | dissipation | breakdown | Shore | of heat |
| | | | length | [% by | Density | quantity | tivity | resistance | in long- | voltage | hardness | radiating |
| | Rubber | Type | [μm] | volume] | [g/cm³] | L(r) | [W/mK] | [m²K/W] | term test | [kV/mm] | [HS] | member |
| Example A1 | S [symbol] | Aluminum | 7 | 60 | 2.34 | 0.15 | 16.2 | AA | AA | 10.5 | 30 | AA |
| | rubber | nitride | | | | | | | | | | |
| Example A2 | S [symbol] | Aluminum | 3 | 80 | 2. [symbol] 0 | 0.22 | 13.0 | A | A | 9.7 | 75 | AA |
| | rubber | nitride | | | | | | | | | | |
| Example A3 | S [symbol] | Silicon | 2 | 60 | 2.31 | 0.29 | 5.1 | A | A | 7.4 | 52 | AA |
| | rubber | carbide | | | | | | | | | | |
| Example A4 | S [symbol] | Boron | 8 | 60 | 1.74 | 0.2 [symbol] | 15. [symbol] | AA | AA | 9.9 | 45 | AA |
| | rubber | nitride | | | | | | | | | | |
| Example A5 | S [symbol] | Graphite | 6 | 60 | 1.72 | 0.23 | 18.5 | A | A | 0.2 | 53 | A |
| | rubber | | | | | | | | | | | |
| Example A6 | S [symbol] | Graphite | 6 | 80 | 1. [symbol] 7 | 0.2 [symbol] | 29.4 | A | A | 0.1 | 72 | A |
| | rubber | | | | | | | | | | | |
| Example A7 | S [symbol] | Silicon | 2 | 7 [symbol] | 2.71 | 0.28 | 6.8 | A | A | 10.2 | 83 | A |
| | rubber | carbide | | | | | | | | | | |
| Example A8 | S [symbol] | Graphite | 6 | [symbol] | 1. [symbol] | 0.21 | 10.9 | A | A | 0.3 | 42 | A |
| | rubber | | | | | | | | | | | |
| Comparative | S [symbol] | Aluminum | 1 [symbol] | 60 | 2.34 | 0.10 | 3.8 | B | B | 10.8 | 62 | B |
| Example A1 | rubber | nitride | | | | | | | | | | |
| Comparative | S [symbol] | Aluminum | 0.1 | 60 | 2.34 | 0.47 | [symbol] .2 | B | B | 9.5 | 76 | B |
| Example A2 | rubber | nitride | | | | | | | | | | |
| Comparative | S [symbol] | Graphite | 6 | 30 | 1.33 | 0.13 | 3.6 | B | B | 0. [symbol] | 23 | B |
| Example A3 | rubber | | | | | | | | | | | |
| Comparative | S [symbol] | Graphite | 0.1 | 30 | 1.33 | 0. [symbol] 1 | 2.3 | C | C | 0.6 | 21 | C |
| Example A4 | rubber | | | | | | | | | | | |

[symbol]

indicates data missing or illegible when filed

TABLE 2

| | | Filler | | | | Integrated | | | | | | Appropri- |
|---|---|---|---|---|---|---|---|---|---|---|---|---|
| | | | Average | | | value of | Thermal | | Heat | Insulation | | ateness |
| | | | maximum | Content | | statistical | conduc- | Thermal | dissipation | breakdown | Shore | of heat |
| | | | length | [% by | Density | quantity | tivity | resistance | in long- | voltage | hardness | radiating |
| | Resin | Type | [μm] | volume] | [g/cm³] | L(r) | [W/mK] | [m²K/W] | term test | [kV/mm] | [HS] | member |
| Example | Acrylic | Aluminum | 7 | 60 | 2.43 | 0.12 | 16.6 | AA | AA | 8.2 | 71 | AA |
| B1 | resin | nitride | | | | | | | | | | |
| Example | Acrylic | Aluminum | 1 | 7 [symbol] | 2.74 | 0.27 | 19.8 | A | A | 7.6 | 79 | AA |
| B2 | resin | nitride | | | | | | | | | | |
| Example | Acrylic | Boron | 4 | 40 | 1.62 | 0.22 | 7.5 | A | A | 8.6 | 72 | AA |
| B3 | resin | nitride | | | | | | | | | | |
| Example | Acrylic | Graphite | 6 | 70 | 1.92 | 0.27 | 18.3 | A | A | 0.2 | 68 | A |
| B4 | resin | | | | | | | | | | | |
| Example | Acrylic | Silicon | 2 | 70 | 2.61 | 0.29 | 5.9 | A | A | 7.1 | 83 | A |
| B5 | resin | carbide | | | | | | | | | | |
| Example | Polyimide | Aluminum | 7 | [symbol] 0 | 2. [symbol] | 0.17 | 1 [symbol] .8 | AA | AA | 9.1 | 69 | AA |
| B6 | | nitride | | | | | | | | | | |
| Example | Polyimide | Boron | 8 | 40 | 1.77 | 0.22 | 8.7 | A | A | 6.3 | 75 | AA |
| B7 | | nitride | | | | | | | | | | |
| Example | Polyimide | CNF | 1 | [symbol] 0 | 1.83 | 0.21 | 27.8 | A | A | 0.2 | 78 | A |
| B8 | | | | | | | | | | | | |
| Example | Polyimide | Graphite | 6 | 70 | 1.99 | 0.28 | 19.8 | A | A | 0.1 | 72 | A |
| B9 | | | | | | | | | | | | |
| Example | Polyimide | Silicon | 2 | 70 | 2.68 | 0.26 | [symbol] .7 | A | A | 7.2 | 85 | A |
| B10 | | carbide | | | | | | | | | | |

[symbol]

indicates data missing or illegible when filed

TABLE 3

| | | Filler | | | | Integrated | | | | | | Appropri- |
|---|---|---|---|---|---|---|---|---|---|---|---|---|
| | | | Average | | | value of | Thermal | | Heat | Insulation | | ateness |
| | | | maximum | Content | | statistical | conduc- | Thermal | dissipation | breakdown | Shore | of heat |
| | | | length | [% by | Density | quantity | tivity | resistance | in long- | voltage | hardness | radiating |
| | Resin | Type | [μm] | volume] | [g/cm³] | L(r) | [W/mK] | [m²K/W] | term test | [kV/mm] | [HS] | member |
| Example | Aromatic | Aluminum | 7 | 60 | 2. [symbol] 2 | 0.13 | 1 [symbol] .2 | A | A | 7. [symbol] | 79 | AA |
| B11 | polyester | nitride | | | | | | | | | | |
| Example | Aromatic | Aluminum | 1 | 70 | 2.70 | 0.28 | 17.8 | A | A | 7.8 | 71 | AA |
| B12 | polyester | nitride | | | | | | | | | | |
| Example | Aromadie | Boron | 8 | 40 | 1.7 [symbol] | 0.19 | 7.8 | A | A | 8.2 | 78 | AA |
| B13 | polyester | nitride | | | | | | | | | | |
| Example | Aromatic | Graphite | [symbol] | 70 | 1.98 | 0.27 | 24.1 | A | A | 0.1 | 71 | A |
| B14 | polyester | | | | | | | | | | | |
| Example | Aromatic | Silicon | 2 | 70 | 2.67 | 0.26 | 6.1 | A | A | 6.9 | 86 | A |
| B15 | polyester | carbide | | | | | | | | | | |
| Example | Epoxy | Aluminum | 7 | [symbol] 0 | 2.42 | 0.18 | 17.0 | AA | AA | 10. [symbol] | [symbol] | AA |
| B16 | resin | nitride | | | | | | | | | | |
| Example | Epoxy | Aluminum | 1 | 75 | 2.73 | 0.21 | 1 [symbol] . [symbol] | A | A | 9.5 | 71 | AA |
| B17 | resin | nitride | | | | | | | | | | |
| Example | Epoxy | Boron | 4 | 40 | 1. [symbol] 0 | 0.23 | [symbol] .1 | AA | AA | 10.2 | [symbol] 1 | AA |
| B18 | resin | nitride | | | | | | | | | | |
| Example | Epoxy | Graphite | [symbol] | 70 | 1.91 | 0.28 | 18. [symbol] | A | A | 0.1 | 71 | A |
| B19 | resin | | | | | | | | | | | |
| Example | Epoxy | Silicon | 2 | 70 | 2. [symbol] 0 | 0.12 | 6.2 | A | A | 8.1 | 81 | A |
| B20 | resin | carbide | | | | | | | | | | |

[symbol]

indicates data missing or illegible when filed

TABLE 4

| | | Filler | | | | Integrated | | | | Insulation | | Appropri- |
|---|---|---|---|---|---|---|---|---|---|---|---|---|
| | | | Average | | | value of | Thermal | | Heat | break- | Shore | ateness |
| | | | maximum | Content | | statistical | conduc- | Thermal | dissipation | down | hard- | of heat |
| | | | length | [% by | Density | quantity | tivity | resistance | in long- | voltage | ness | radiating |
| | Resin | Type | [μm] | volume] | [g/cm³] | L(r) | [W/mK] | [m²K/W] | term test | [kV/mm] | [HS] | member |
| Comparative | Acrylic | Aluminum | 0.8 | 60 | 2.43 | 0.65 | 3.6 | B | B | 6.3 | 78 | B |
| Example B1 | resin | nitride | | | | | | | | | | |
| Comparative | Acrylic | CNF | 1 | 15 | 1.33 | 0.20 | [symbol] .1 | B | B | [symbol] .2 | 77 | B |
| Example B2 | resin | | | | | | | | | | | |
| Comparative | Acrylic | Graphite | 0.1 | 15 | 1.35 | 0.49 | 2.3 | C | C | [symbol] .1 | 80 | C |
| Example B3 | resin | | | | | | | | | | | |
| Comparative | Polyimide | Aluminum | 0.8 | [symbol] 0 | 2.53 | 0.63 | 3.7 | B | B | 7.2 | 79 | B |
| Example B4 | | nitride | | | | | | | | | | |
| Comparative | Polyimide | CNF | [symbol] | 5 | 1.46 | 0.08 | 4.9 | B | B | [symbol] .3 | 74 | B |
| Example B5 | | | | | | | | | | | | |
| Comparative | Polyimide | Graphite | 0.1 | 5 | 1.47 | 0.43 | 2.6 | C | C | 3.8 | 80 | C |
| Example B6 | | | | | | | | | | | | |
| Comparative | Aromatic | Aluminum | 0.8 | [symbol] 0 | 2.52 | 0. [symbol] 0 | 4.7 | B | B | 7.2 | 71 | B |
| Example B7 | polyester | nitride | | | | | | | | | | |
| Comparative | Aromatic | Graphite | 6 | 10 | 1.48 | 0.15 | 4.7 | B | B | 4.5 | 69 | B |
| Example B8 | polyester | | | | | | | | | | | |
| Comparative | Aromatic | Graphite | 0.1 | 10 | 1.48 | 0. [symbol] 8 | 3.6 | C | C | 3.7 | 81 | C |
| Example B9 | polyester | | | | | | | | | | | |
| Comparative | Epoxy | Aluminum | 0.8 | 60 | 2.42 | 0.47 | 4.2 | B | B | 9.4 | 71 | B |
| Example B10 | resin | nitride | | | | | | | | | | |
| Comparative | Epoxy | Graphite | [symbol] | 20 | 1.37 | 0.12 | 6.7 | B | B | 1.2 | 67 | B |
| Example B11 | resin | | | | | | | | | | | |
| Comparative | Epoxy | Graphite | 0.1 | 20 | 1.37 | 0.64 | 3.9 | C | C | 1.8 | 83 | C |
| Example B12 | resin | | | | | | | | | | | |

[symbol]

indicates data missing or illegible when filed

As shown in Tables 1 to 4, it can be seen that, the decrease in heat dissipation of the composition film of the present examples is suppressed after repeating the heat dissipation as compared with Comparative Examples A1 to A4 and B1 to B12 in which at least one of the average maximum length of the filler, the density of the composition film, or the integrated value of the statistical quantity L(r) of the composition film is out of the range of the present disclosure.

The composition film and the heat radiating member according to the exemplary embodiment of the present disclosure include the following aspects.

(((1)))

A composition film comprising:
at least one compound selected from the group consisting of a resin and a rubber; and
a filler which is dispersed in the compound and has an average maximum length of 0.05 μm or more and 10 μm or less,
wherein a density is 1.50 g/cm³ or more and 2.80 g/cm³ or less, and
in a spatial distribution of the filler presented in an evaluation region, an integrated value of a statistical quantity L(r) represented by Equation (1) at an interparticle distance r of 0.05 μm or more and 0.30 μm or less is 0 or more and 0.30 or less,

$$L ( r ) := \sqrt{K ( r ) / π} - r \qquad ( 1 )$$

(in Equation (1), r represents the interparticle distance, and K(r) represents a Ripley's K function K(r) represented by Equation (2)),

$$K ( r ) := \frac{{\sum }_{i \neq j}^{N} 1 ( \vert {X}_{i} - {X}_{j} \vert \leq r ) / s ( \vert {X}_{i} - {X}_{j} \vert )}{{λ}^{2}} \qquad ( 2 )$$

(in Equation (2), 1(|Xᵢ−Xⱼ|≤r) represents an indicator function, Xᵢ and Xⱼ each represent a coordinate of point i or point j, |Xᵢ−Xⱼ| represents a Euclidean distance between the coordinate Xᵢ and the coordinate Xⱼ, r represents the interparticle distance, s(|Xᵢ−Xⱼ|) represents an edge correction factor s(x) of the evaluation region represented by Equation (3), x=|Xᵢ−Xⱼ| is satisfied, N represents a total number of particles in the evaluation region, and λ represents a number density of particles in the evaluation region),

$$s ( x ) := {L}_{x} {L}_{y} - \frac{x}{π} ( 2 {L}_{x} + 2 {L}_{y} - x ) \qquad ( 3 )$$

(in Equation (3), Lₓ and L_{y} each represent a length (μm) of sides of the evaluation region in an x-axis direction and a y-axis direction, x=Xᵢ−Xⱼ| is satisfied, Xᵢ and Xⱼ each represent a coordinate of point i or point j, and |Xᵢ−Xⱼ| represents a Euclidean distance between the coordinate Xᵢ and coordinate Xⱼ).
   (((2)))

The composition film according to (((1))),
wherein the filler has an average maximum length of 1.0 μm or more and 10 μm or less.
   (((3)))

The composition film according to (((1))) or (((2))),
wherein the density is 1.60 g/cm³ or more and 2.80 g/cm³ or less.
   (((4)))

The composition film according to any one of (((1))) to (((3))),
wherein the integrated value of the statistical quantity L(r) represented by Equation (1) is 0 or more and 0.28 or less.
   (((5)))

The composition film according to any one of (((1))) to (((4))),
wherein an insulation breakdown voltage is 5.0 kV/mm or more.
   (((6)))

The composition film according to (((5))),
wherein the insulation breakdown voltage is 6.0 kV/mm or more and 20.0 kV/mm or less.
   (((7)))

The composition film according to any one of (((1))) to (((6))),
wherein a Shore hardness is 25 Hs or more and 80 Hs or less.
   (((8)))

The composition film according to (((7))),
wherein the Shore hardness is 25 Hs or more and 75 Hs or less.
   (((9)))

The composition film according to any one of (((1))) to (((8))),
wherein the composition film contains, as the filler, at least one selected from the group consisting of silicon carbide, aluminum nitride, and boron nitride.
   (((10)))

The composition film according to (((9))),
wherein the composition film contains, as the filler, at least one of aluminum nitride or boron nitride.
   (((11)))

The composition film according to any one of (((1))) to (((10))),
wherein a thermal conductivity is 5.0 W/mK or more.
   (((12)))

The composition film according to (((11))),
wherein the thermal conductivity is 6.0 W/mK or more and 30.0 W/mK or less.
   (((13)))

The composition film according to any one of (((1))) to (((12))),
wherein a thermal resistance is 1.0×10⁻³ m²K/W or less.
   (((14)))

The composition film according to (((13))),
wherein the thermal resistance is 5.0×10⁻⁴ m²K/W or less.
   (((15)))

A heat radiating member comprising:
the composition film according to any one of (((1))) to (((14))).
   (((16)))

The heat radiating member according to (((15))),
wherein the heat radiating member has the composition film as a single layer film.
   (((17)))

The heat radiating member according to (((15))),
wherein the heat radiating member has a laminated film in which two or more of the composition films are laminated.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A composition film comprising:
at least one compound selected from the group consisting of a resin and a rubber; and
a filler which is dispersed in the compound and has an average maximum length of 0.05 μm or more and 10 μm or less,
wherein a density is 1.50 g/cm³ or more and 2.80 g/cm³ or less, and
in a spatial distribution of the filler presented in an evaluation region, an integrated value of a statistical quantity L(r) represented by Equation (1) at an interparticle distance r of 0.05 μm or more and 0.30 μm or less is 0 or more and 0.30 or less,
$$L ( r ) := \sqrt{K ( r ) / π} - r \qquad ( 1 )$$
(in Equation (1), r represents the interparticle distance, and K(r) represents a Ripley's K function K(r) represented by Equation (2)),
$$K ( r ) := \frac{{\sum }_{i \neq j}^{N} 1 ( \vert {X}_{i} - {X}_{j} \vert \leq r ) / s ( \vert {X}_{i} - {X}_{j} \vert )}{{λ}^{2}} \qquad ( 2 )$$
(in Equation (2), 1(|Xᵢ−Xⱼ|≤r) represents an indicator function, Xᵢ and Xⱼ each represent a coordinate of point i or point j, |Xᵢ−Xⱼ| represents a Euclidean distance between the coordinate Xᵢ and the coordinate Xⱼ, r represents the interparticle distance, s(|Xᵢ−Xⱼ|) represents an edge correction factor s(x) of the evaluation region represented by Equation (3), x=|Xᵢ−Xⱼ| is satisfied, N represents a total number of particles in the evaluation region, and λ represents a number density of particles in the evaluation region),
$$s ( x ) := {L}_{x} {L}_{y} - \frac{x}{π} ( 2 {L}_{x} + 2 {L}_{y} - x ) \qquad ( 3 )$$
(in Equation (3), Lₓ and L_{y} each represent a length (μm) of sides of the evaluation region in an x-axis direction and a y-axis direction, x=|Xᵢ−Xⱼ| is satisfied, Xᵢ and Xⱼ each represent a coordinate of point i or point j, and |Xᵢ−Xⱼ| represents a Euclidean distance between the coordinate Xᵢ and coordinate Xⱼ).

2. The composition film according to claim 1,
wherein the filler has an average maximum length of 1.0 μm or more and 10 μm or less.

3. The composition film according to claim 1,
wherein the density is 1.60 g/cm³ or more and 2.80 g/cm³ or less.

4. The composition film according to claim 1,
wherein the integrated value of the statistical quantity L(r) represented by Equation (1) is 0 or more and 0.28 or less.

5. The composition film according to claim 1,
wherein an insulation breakdown voltage is 5.0 kV/mm or more.

6. The composition film according to claim 5,
wherein the insulation breakdown voltage is 6.0 kV/mm or more and 20.0 kV/mm or less.

7. The composition film according to claim 1,
wherein a Shore hardness is 25 Hs or more and 80 Hs or less.

8. The composition film according to claim 7,
wherein the Shore hardness is 25 Hs or more and 75 Hs or less.

9. The composition film according to claim 1,
wherein the composition film contains, as the filler, at least one selected from the group consisting of silicon carbide, aluminum nitride, and boron nitride.

10. The composition film according to claim 9,
wherein the composition film contains, as the filler, at least one of aluminum nitride or boron nitride.

11. The composition film according to claim 1,
wherein a thermal conductivity is 5.0 W/mK or more.

12. The composition film according to claim 11,
wherein the thermal conductivity is 6.0 W/mK or more and 30.0 W/mK or less.

13. The composition film according to claim 1,
wherein a thermal resistance is 1.0×10⁻³ m²K/W or less.

14. The composition film according to claim 13,
wherein the thermal resistance is 5.0×10⁻⁴ m²K/W or less.

15. A heat radiating member comprising:
the composition film according to claim 1.

16. A heat radiating member comprising:
the composition film according to claim 2.

17. A heat radiating member comprising:
the composition film according to claim 3.

18. A heat radiating member comprising:
the composition film according to claim 4.

19. The heat radiating member according to claim 15,
wherein the heat radiating member has the composition film as a single layer film.

20. The heat radiating member according to claim 15,
wherein the heat radiating member has a laminated film in which two or more of the composition films are laminated.
